(19) United States
(12) Patent Application Publication
(10) Pub. No.: US 2025/0324891 A1
(43) Pub. Date: Oct. 16, 2025

(54) DISPLAY DEVICE, ELECTRONIC DEVICE AND METHOD OF MANUFACTURING DISPLAY DEVICE

(71) Applicant: Samsung Display Co., LTD., Yongin-si (KR)

(72) Inventors: Kyung Hee LEE, Yongin-si (KR); Duck Jong SUH, Yongin-si (KR); Ho LIM, Yongin-si (KR); Tae Min KIM, Yongin-si (KR); Dong Geun SHIN, Yongin-si (KR); Seung Hee LEE, Yongin-si (KR)

(21) Appl. No.: 19/074,166

(22) Filed: Mar. 7, 2025

(30) Foreign Application Priority Data
Apr. 16, 2024 (KR) 10-2024-0050924

(51) Int. Cl. H10K 59/80; H10K 59/12; H10K 59/38

(52) U.S. Cl. CPC H10K 59/873; H10K 59/1201; H10K 59/38

(57) ABSTRACT

A display device includes: a display element layer including a light emitting element; an encapsulation layer on the display element layer, the encapsulation layer being formed as a single layer; and a light control layer overlapping with the encapsulation layer, the light control layer including a light control pattern layer including a first wavelength conversion layer, a second wavelength conversion layer, and a light transmission layer, wherein the light emitting element includes a first electrode, an organic light emitting portion on the first electrode, and a second electrode on the organic light emitting portion, and wherein a distance between a top surface of the second electrode and a bottom surface of the light control pattern layer is in a range of 10 nanometers (nm) to 2000 nm.

### CROSS-REFERENCE TO RELATED APPLICATION

The present application claims priority to and the benefit of Korean Patent Application No. 10-2024-0050924, filed on Apr. 16, 2024, in the Korean Intellectual Property Office, the entire disclosure of which is incorporated herein by reference.

### BACKGROUND

### 1. Field

Aspects of some embodiments of the present disclosure generally relate to a display device, electronic device and a method of manufacturing a display device.

### 2. Description of the Related Art

With the development of information technologies, the importance of display devices which provide a connection medium between users and information increases. Accordingly, research and development of display devices has been continuously conducted.

A display device may include a plurality of pixels for displaying images, and each of the pixels may include a light emitting element emitting light and a driving element connected to the light emitting element. When the light emitting element emits light toward a display surface of the display device, a light loss problem may occur, and a structure for reducing or preventing this problem may be desirable.

The above information disclosed in this Background section is only for enhancement of understanding of the background and therefore the information discussed in this Background section does not necessarily constitute prior art.

### SUMMARY

Aspects of some embodiments of the present disclosure include a display device and a method of manufacturing a display device, in which the light output efficiency of the display device is relatively improved and the thickness of the display device is relatively decreased.

According to some embodiments of the present disclosure, a display device includes: a display element layer including a light emitting element; an encapsulation layer on the display element layer, the encapsulation layer being formed as a single layer; and a light control layer overlapping with the encapsulation layer, wherein the light emitting element includes a first electrode, an organic light emitting portion on the first electrode, and a second electrode on the organic light emitting portion, wherein the light control layer includes a light control pattern layer including a first wavelength conversion layer, a second wavelength conversion layer, and a light transmission layer, and wherein a distance between a top surface of the second electrode and a bottom surface of the light control pattern layer is 10 nm to 2000 nm.

According to some embodiments, the encapsulation layer may be deposited by using Plasma-Enhanced Atomic Layer Deposition (PEALD) or Atomic Layer Deposition (ALD).

According to some embodiments, the encapsulation layer may have a thickness of 10 nm to 1000 nm.

According to some embodiments, a bottom surface of the encapsulation layer may be in contact with the second electrode, and a top surface of the encapsulation layer may be in contact with the first wavelength conversion layer, the second wavelength conversion layer, and the light transmission layer.

According to some embodiments, the encapsulation layer may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

According to some embodiments, the display device may further include a first capping layer over the light control pattern layer. According to some embodiments, the first capping layer may include an inorganic material, and have a thickness of 100 nm to 1000 nm.

According to some embodiments, the display device may further include a low refractive layer on the first capping layer. According to some embodiments, the low refractive layer may have a refractive index smaller than a refractive index of the light control pattern layer. According to some embodiments, the low refractive layer may have a refractive index of 1.1 to 1.4.

According to some embodiments, the display device may further include a color filter layer on the light control layer. According to some embodiments, the filter layer may include a first color filter, a second color filter, and a third color filter. According to some embodiments, the first color filter may allow light of red to be selectively transmitted therethrough, the second color filter may allow light of green to be selectively transmitted therethrough, and the third color filter may allow light of blue to be selectively transmitted therethrough.

According to some embodiments, the display device may further include a planarization layer on the color filter layer. According to some embodiments, the planarization layer may include an organic material, and have a thickness in a range of 1000 nm to 10000 nm.

According to some embodiments, the display device may further include: a first sub-pixel area emitting light of a first color; a second sub-pixel area emitting light of a second color; a third sub-pixel area emitting light of a third color; and a bank between the first to third sub-pixel areas. According to some embodiments, the first wavelength conversion layer may be in the first sub-pixel area, the second wavelength conversion layer may be in the second sub-pixel area, and the light transmission layer may be in the third sub-pixel area.

According to some embodiments, the display device may further include an anti-reflection film on the planarization layer.

According to some embodiments of the present disclosure, a display device includes: a display area having pixels therein, the display area including a first sub-pixel area, a second sub-pixel area, and a third sub-pixel area; a display element layer including a light emitting element forming the pixels; an encapsulation layer on the display element layer; and a light control layer overlapping with the display element layer, wherein the light emitting element includes a first electrode, an organic light emitting portion on the first electrode, and a second electrode on the organic light emitting portion, wherein the light control layer includes a light control pattern layer including a first wavelength conversion layer in the first sub-pixel area, a second wavelength conversion layer in the second sub-pixel area, and a light transmission layer in the third sub-pixel area, and wherein a distance between a top surface of the second electrode and a bottom surface of the light control pattern layer is 10 nm to 1000 nm.

According to some embodiments, the encapsulation layer may be formed as a single layer. According to some embodiments, a bottom surface of the encapsulation layer may be in contact with the second electrode, and a top surface of the encapsulation layer may be in contact with the first wavelength conversion layer, the second wavelength conversion layer, and the light transmission layer. According to some embodiments, the encapsulation layer may include an inorganic material.

According to some embodiments, the display device may further include: a first capping layer on the light control pattern layer; and a low refractive layer on the first capping layer. According to some embodiments, the low refractive layer may have a refractive index lower than a refractive index of the light control pattern layer. According to some embodiments, the first capping layer may be in contact with the light control pattern layer. According to some embodiments, the first capping layer may include an inorganic material, and have a thickness of 100 nm to 1000 nm. The low refractive layer may have a refractive index of 1.1 to 1.4.

According to some embodiments, the display device may further include: a color filter layer on the light control layer; and a planarization layer on the color filter layer. According to some embodiments, the color filter layer may include a first color filter, a second color filter, and a third color filter. According to some embodiments, the first color filter may overlap the first sub-pixel area, the second color filter may overlap the second sub-pixel area, and the third color filter may overlap the third sub-pixel area. According to some embodiments, the planarization layer may include an organic material, and have a thickness of 1500 nm to 10000 nm.

According to some embodiments, the display device may include a bank on the encapsulation layer. According to some embodiments, the bank may include an opening. According to some embodiments, the opening may overlap the first sub-pixel area, the second sub-pixel area, and the third sub-pixel area.

According to some embodiments, the first wavelength conversion layer and the second wavelength conversion layer may include a quantum dot. According to some embodiments, the light transmission layer may include a scatterer.

According to some embodiments, the display device may further include an anti-reflection film on the planarization layer.

According to some embodiments of the present disclosure, there is provided a method of manufacturing a display device, the method including: forming a display element layer including a light emitting element; forming an encapsulation layer on the display element layer; and forming a light control layer overlapping the encapsulation layer, wherein the light emitting element includes a first electrode, an organic light emitting portion on the first electrode, and a second electrode on the organic light emitting portion, wherein the light control layer includes a light control pattern layer including a first wavelength conversion layer, a second wavelength conversion layer, and a light transmission layer, wherein a distance between the second electrode and the light control pattern layer is 10 nm to 2000 nm, and wherein the forming of the encapsulation layer includes depositing the encapsulation layer, by using Plasma-Enhanced Atomic Layer Deposition (PEALD) or Atomic Layer Deposition (ALD).

According to some embodiments, the encapsulation layer may be formed as a single layer.

An electronic device includes a processor to provide input image data; and a display device to display an image based on the input image data. The display device includes a display element layer including a light emitting element; an encapsulation layer on the display element layer, the encapsulation layer being formed as a single layer; and a light control layer overlapping with the encapsulation layer, the light control layer including a light control pattern layer including a first wavelength conversion layer, a second wavelength conversion layer, and a light transmission layer. The light emitting element includes a first electrode, an organic light emitting portion on the first electrode, and a second electrode on the organic light emitting portion. The distance between a top surface of the second electrode and a bottom surface of the light control pattern layer is in a range of 10 nanometers (nm) to 2000 nm.

### BRIEF DESCRIPTION OF THE DRAWINGS

Aspects of some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device according to some embodiments of the present disclosure.

FIGS. 2, 3, and 4 are schematic plan views illustrating aspects of a pixel shown in FIG. 1.

FIG. 5 is a schematic sectional view illustrating a display panel shown in FIG. 1.

FIG. 6 is a circuit diagram illustrating aspects of a sub-pixel included in a pixel shown in each of FIGS. 2 to 4.

FIG. 7 is a schematic sectional view illustrating aspects of a light emitting element shown in FIG. 6.

FIG. 8 is a schematic sectional view illustrating aspects of the light emitting element shown in FIG. 6.

FIG. 9 is a schematic sectional view illustrating aspects of a pixel including the light emitting element shown in FIG. 7 or 8.

FIG. 10 is a flowchart illustrating aspects of a method of manufacturing the display device according to some embodiments of the present disclosure.

FIG. 11 is a schematic block diagram illustrating an electronic device 1000 including a display device in accordance with an embodiment.

FIG. 12 is a schematic diagram illustrating an example where the electronic device 1000 of FIG. 11 is a smartphone.

FIG. 13 is a schematic diagram illustrating an example where the electronic device 1000 of FIG. 11 is a tablet computer.

### DETAILED DESCRIPTION

Aspects of some embodiments of the present disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

Aspects of some embodiments of the present disclosure relate to a display device. Hereinafter, a display device according to some embodiments of the present disclosure will be described with reference to the accompanying drawings.

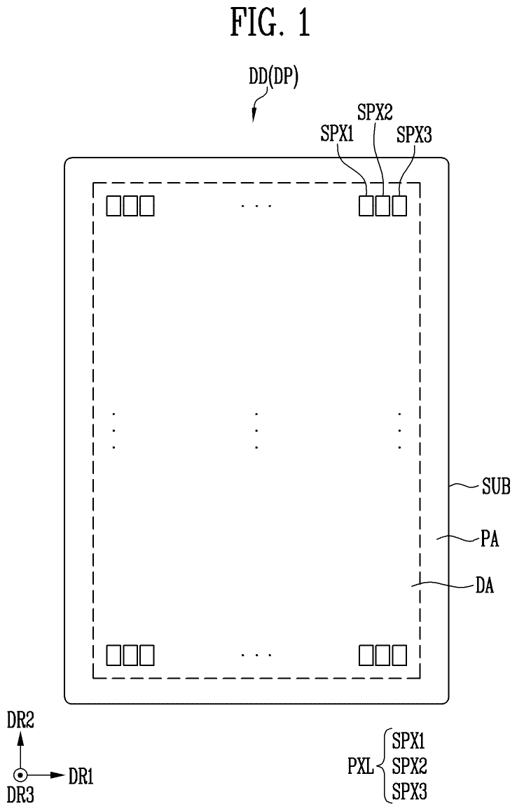

FIG. 1 is a schematic plan view illustrating a display device according to some embodiments of the present disclosure.

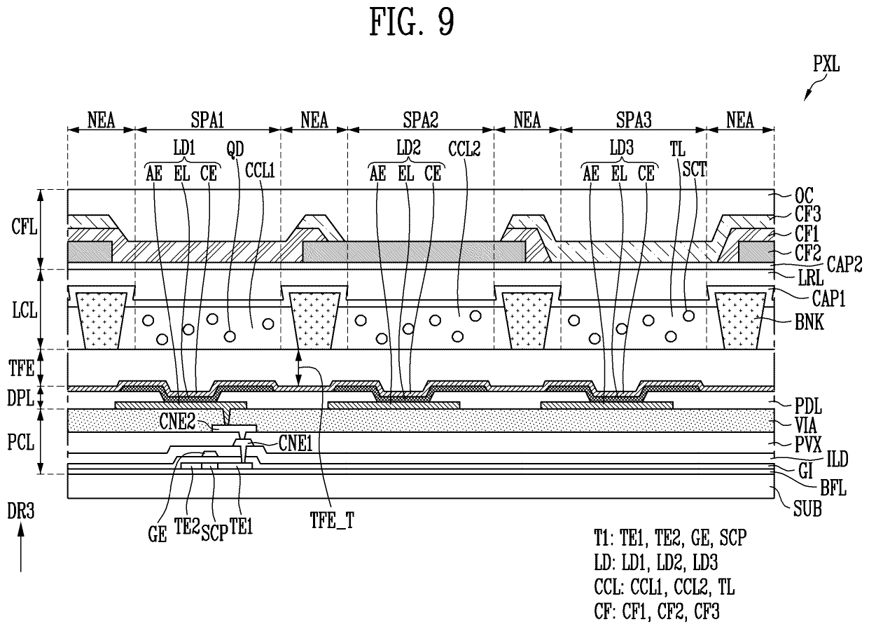

Referring to FIG. 1, a display panel DP (or display device DD) may display an image. The display panel DP may include a light emitting element LD (see FIG. 9). Self-luminescent display panels, such as an Organic Light Emitting Display panel (OLED panel) using an organic light emitting diode as a light emitting element, a micro-LED or nano-LED display panel using a micro LED or nano LED as a light emitting element, and a Quantum Dot Organic Light Emitting Display panel (QD OLED panel) using a quantum dot and an organic light emitting diode, may be used as the display panel DP. In addition, non-luminescent display panels, such as a Liquid Crystal Display panel (LCD panel), an Electro-Phoretic Display panel (EPD panel), and an Electro-Wetting Display panel (EWD panel), may be used as the display panel DP. When a non-luminescent display panel is used as the display panel DP, the display device DD may include a backlight unit which supplies light to the display panel DP. However, embodiments according to the present disclosure are not limited to a specific example. Hereinafter, in the present disclosure, embodiments in which a Quantum Dot Organic Light Emitting Display panel (QD OLED panel) is used as the display panel DP will be described.

The display panel DP may include a substrate SUB and pixels PXL provided on the substrate SUB.

The substrate SUB may include a transparent insulating material to enable light to be transmitted therethrough. The substrate SUB may be a rigid substrate or a flexible substrate. The rigid substrate may be, for example, one of a glass substrate, a quartz substrate, a glass ceramic substrate, and a crystalline glass substrate.

The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The display device DD (or the display panel DP) may have various shapes. According to some embodiments, the display device DD may be provided in a rectangular shape, but embodiments according to the present disclosure are not limited thereto. For example, the display device DD may have a circular or elliptical shape. Also, the display device DD may include an angular corner and/or a curved corner. For convenience, in FIG. 1, it is illustrated that the display device DD has a rectangular plate shape. Also, in FIG. 1, an extending direction of a short side of the display device DD (e.g., a lateral direction) (or a horizontal direction as a “row” direction of the pixel PXL) is indicated as a first direction DR1, and an extending direction of a long side of the display device DD (e.g., a longitudinal direction) (or a “column” direction of the pixel PXL) is indicated as a second direction DR2. In addition, a display direction of the display device DD or a normal of a plane on which the substrate SUB is located is indicated as a third direction DR3.

The substrate SUB (and the display device DD) may include a display area DA for display an image and a peripheral area PA (or non-display area) surrounding the display area DA (or except the display area DA). The substrate SUB may include the display area DA including pixel areas in which the respective pixels PXL are located and the peripheral area PA located at the periphery of (e.g., surrounding or outside a footprint of) the display area DA (or adjacent to the display area DA).

The peripheral area PA may be located adjacent to the display area DA. The peripheral area PA may be provided at least one side of the display area DA. According to some embodiments, the peripheral area PA may surround a circumference (or edge) of the display area DA. According to some embodiments, the peripheral area PA may be a bezel area of the display device DD.

The pixels PXL may be located in the display area DA on the substrate SUB. The peripheral area PA may be located at the periphery of the display area DA. The peripheral area PA may have a structure for protecting components included in the pixels PXL located in the display area DA, but embodiments according to the present disclosure are not limited thereto. For example, a line unit connected to the pixels PXL and a driving unit connected to the line unit to drive the pixels PXL may be provided in the peripheral area PA.

The pixel PXL may include a plurality of sub-pixels SPX1, SPX2, and SPX3. According to some embodiments, the pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be sequentially located in the first direction DR1. However, embodiments according to the present disclosure are not limited thereto, and the first sub-pixel SPX1, the second sub-pixel SPX2, and the third sub-pixel SPX3 may be sequentially arranged in the second direction DR2 intersecting the first direction DR1.

The first to third sub-pixels SPX1, SPX2, and SPX3 may emit light of different colors. According to some embodiments, the first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm. However, embodiments according to the present disclosure are not limited thereto. The colors, kinds, and/or numbers of pixels constituting the pixel PXL are not particularly limited. According to some embodiments, the color of light emitted from each of the first to third sub-pixels SPX1, SPX2, and SPX3 may be variously changed. Hereinafter, when first to third sub-pixels SPX1, SPX2, and SPX3 are inclusive designated, the first to third sub-pixels SPX1, SPX2, and SPX3 may be designated as a pixel PXL.

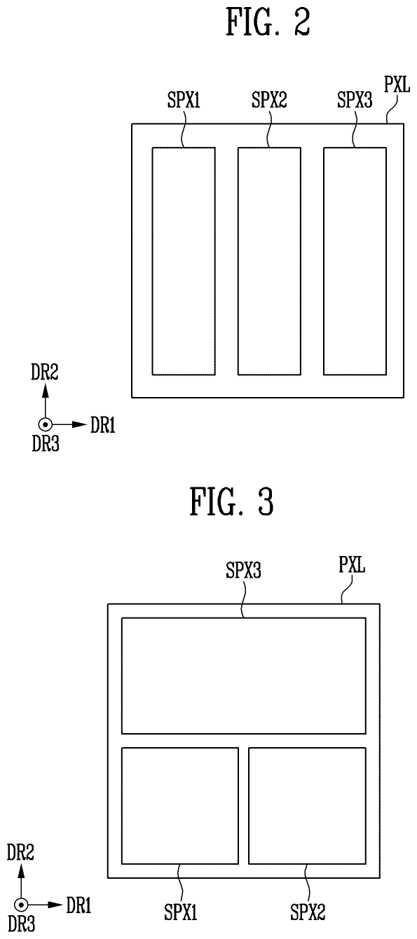

FIGS. 2, 3, and 4 are schematic plan views illustrating embodiments of the pixel shown in FIG. 1.

A first sub-pixel SPX1, a second sub-pixel SPX2, and a third sub-pixel SPX3, which are illustrated in each of FIGS. 2 to 4, may be connected to any one data line among data lines and at least one scan line among scan lines.

Each of the first sub-pixel SPX1, the second sub-pixel SPX2, and the third sub-pixel SPX3 may have a rectangular, square or polygonal planar shape.

Referring to FIG. 2, each of a first sub-pixel SPX1, a second sub-pixel SPX2, and a third sub-pixel SPX3 may have a rectangular planar shape having short sides in the first direction DR1 and long sides in the second direction DR2. However, embodiments according to the present disclosure are not limited thereto. According to some embodiments, each of the first sub-pixel SPX1, the second sub-pixel SPX2, and the third sub-pixel SPX3 may have a square or rhombic planar shape including sides having the same length in the first direction DR1 and the second direction DR2. According to some embodiments, the first sub-pixel SPX1, the second sub-pixel SPX2, and the third sub-pixel SPX3 may be arranged in the first direction DR1. According to some embodiments, areas of the first to third sub-pixels SPX1, SPX2, and SPX3 may be the same (or substantially the same), but embodiments according to the present disclosure are not limited thereto. For example, at least one of the areas of the first to third sub-pixels SPX1, SPX2, and SPX3 may be different from another of the areas of the first to third sub-pixels SPX1, SPX2, and SPX3. Alternatively, any two of the area of the first sub-pixel SPX1, the area of the second sub-pixel SPX2, and the area of the third sub-pixel SPX3 may be substantially the same, and the other of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. Alternatively, the area of the first sub-pixel SPX1, the area of the second sub-pixel SPX2, and the area of the third sub-pixel SPX3 may be different from one another.

Referring to FIG. 3, a first sub pixel SPX1 may be arranged with any one of a second sub-pixel SPX2 and a third sub-pixel SPX3 in the first direction DR1, and be arranged with the other of the second sub-pixel SPX2 and the third sub-pixel SPX3 in the second direction DR2. For example, the first sub-pixel SPX1 may be arranged side by side with the second sub-pixel SPX2 in the first direction DR1, and be arranged with the third sub-pixel SPX3 in the second direction DR2. According to some embodiments, the third sub-pixel SPX3 may be adjacent to the first sub-pixel SPX1 and the second sub-pixel SPX2 along the second direction DR2. According to some embodiments, the third sub-pixel SPX3 may be arranged with the first sub-pixel SPX1 and the second sub-pixel SPX2 in the second direction DR2. According to some embodiments, areas of the first and second sub-pixels SPX1 and SPX2 may be the same (or substantially the same), and an area of the third sub-pixel SPX3 may be different from each of the areas of the first and second sub-pixels SPX1 and SPX2. For example, the area of the third sub-pixel SPX3 may be wider than each of the areas of the first and second sub-pixels SPX1 and SPX2.

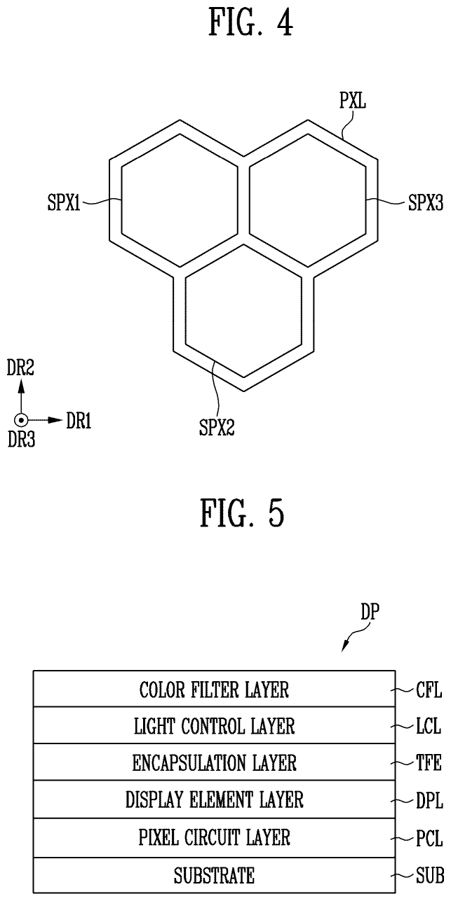

Referring to FIG. 4, each of a first sub-pixel SPX1, a second sub-pixel SPX2, and a third sub-pixel SPX3 may have a hexagonal or regular hexagonal planar shape. According to some embodiments, two adjacent surfaces among six surfaces of each of the first to third sub-pixels SPX1 to SPX3 may face one surfaces of adjacent sub-pixels SPX.

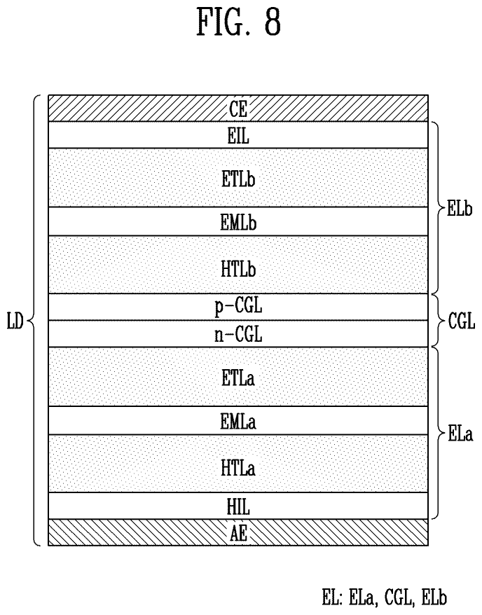

Each of the first sub-pixel SPX1, the second sub-pixel SPX2, and the third sub-pixel SPX3 may include a light emitting element (e.g., a light emitting element LD shown in FIG. 7 or 8) emitting light, and the light emitting element may include an organic light emitting element having an organic layer.

FIG. 5 is a schematic sectional view illustrating the display panel shown in FIG. 1.

Referring to FIG. 5, the display panel DP may include a substrate SUB, a pixel circuit layer PCL, a display element layer DPL, an encapsulation layer TFE, a light control layer LCL, and a color filter layer CFL. According to some embodiments, the substrate SUB, the pixel circuit layer PCL, the display element layer DPL, the encapsulation layer TFE, the light control layer LCL, and the color filter layer CFL may be sequentially stacked in the third direction DR3.

The pixel circuit layer PCL may be provided on the substrate SUB, and include a plurality of transistors and signal lines connected to the transistors. For example, each transistor may be provided in a form in which a semiconductor layer, a gate electrode, a source electrode, and a drain electrode are sequentially stacked with an insulating layer interposed therebetween. The semiconductor layer may include at least one of amorphous silicon, monocrystalline silicon, polycrystalline silicon, low temperature poly-silicon, an organic semiconductor, and an oxide semiconductor. The gate electrode, the source electrode, and the drain electrode may include one of aluminum (Al), copper (Cu), titanium (Ti), and molybdenum (Mo), but embodiments according to the present disclosure are not limited thereto. Also, the pixel circuit layer PCL may include at least one insulating layers.

The display element layer DPL may be located on the pixel circuit layer PCL. The display element layer DPL may include a light emitting element (e.g., a light emitting element LD shown in FIG. 7 or 8) emitting light. The light emitting element may be, for example, an organic light emitting diode, but embodiments according to the present disclosure are not limited thereto.

The encapsulation layer TFE may be located on the display element layer DPL. The encapsulation layer TFE may be an encapsulation substrate or be provided in the form of an encapsulation film formed as a single layer. However, embodiments according to the present disclosure are not limited thereto, and the encapsulation layer TFE may have a multi-layer structure.

When the encapsulation layer TFE is provide in the form of the encapsulation film formed as the single layer, the encapsulation layer TFE may include an inorganic layer. According to some embodiments, when the encapsulation layer TFE is formed as a single layer, the encapsulation layer TFE may be formed of a single material. According to some embodiments, when the encapsulation layer TFE is formed as the single layer, the encapsulation layer TFE may be one layer in which an interface of two or more layers is not observed.

When the encapsulation layer TFE is provided in the form of an encapsulation film formed as a multi-layer, the encapsulation layer TFE may include an organic layer and an inorganic layer. For example, the encapsulation TFE formed as the multi-layer may be provided in a form in which an inorganic layer, an organic layer, and an inorganic layer are sequentially stacked.

The encapsulation layer TFE may prevent or reduce instances of contaminants such as external air and moisture infiltrating into the display element layer DPL and the pixel circuit layer PCL. The encapsulation layer TFE in accordance with the present disclosure is characterized by relatively decreasing the thickness of the display device DD and relatively improving the light output efficiency of the display device DD. This will be described later with reference to FIG. 9.

The light control layer LCL may be located on the encapsulation layer TFE. The light control layer LCL may include elements for converting at least a portion of light emitted from the display element layer DPL into light of a specific color and relatively improving light output efficiency. According to some embodiments, the light control layer LCL may include a light control pattern layer CCL (see FIG. 9) and a low refractive layer LRL (see FIG. 9). However, embodiments according to the present disclosure are not limited thereto. According to some embodiments, the low refractive layer LRL may be omitted.

In FIG. 5, it is illustrated that the light control layer LCL and the encapsulation layer TFE are sequentially stacked on the display element layer DPL. However, embodiments according to the present disclosure are not limited thereto. The light control layer LCL may be located under the display element layer DPL. For example, the light control layer LCL may be located under the display element layer DPL in the opposite direction of the third direction DR3. The light control layer LCL may overlap the display element layer DPL, and the display element layer DPL may be located above or under the light control layer LCL.

The color filter layer CFL may be located on the light control layer LCL. The color filter layer CFL may allow light passing through the light control layer LCL (or the display element layer DPL) to be selectively transmitted therethrough. The color filter layer CFL may include first to third color filters CF1, CF2, and CF3 (see FIG. 9).

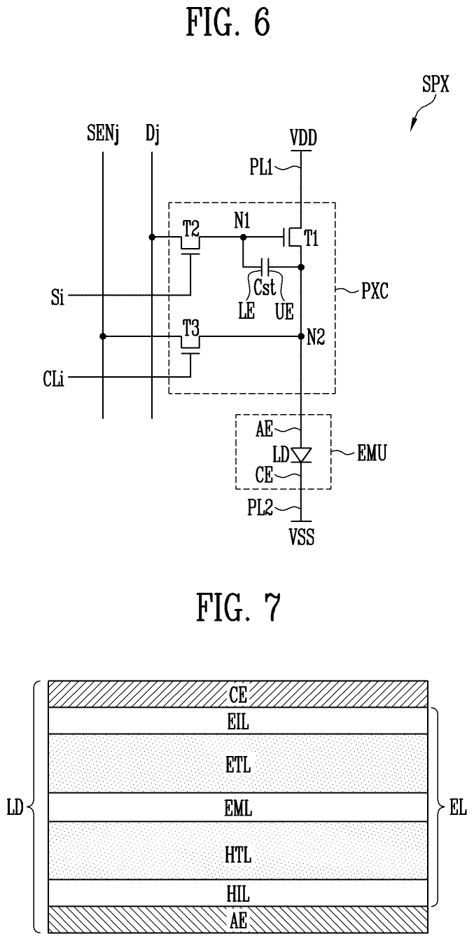

FIG. 6 is a circuit diagram illustrating aspects of the sub-pixel included in the pixel shown in each of FIGS. 2 to 4 according to some embodiments. Although FIG. 6 illustrates various components in a sub-pixel according to some embodiments, embodiments according to the present disclosure are not limited thereto, and according to some embodiments, the sub-pixel may include additional components or fewer components without departing from the spirit and scope of embodiments according to the present disclosure.

A sub-pixel SPX shown in FIG. 6 may be any one of the sub-pixels SPX1, SPX2, and SPX3 shown in FIG. 1, and sub-pixels SPX1, SPX2, and SPX3 arranged in a display area of each display device DD may be configured substantially identical or similar to one another.

In FIG. 6, for convenience, a sub-pixel SPX located on an ith pixel row (or ith horizontal line) and a jth pixel column is illustrated (i and j are natural numbers).

Referring to FIG. 6, the sub-pixel SPX may include a light emitting unit EMU which generates light with a luminance corresponding to a data signal. Also, the sub-pixel SPX may further include a pixel circuit for driving the light emitting unit EMU.

The light emitting unit EMU may include a light emitting element LD connected between a first power line PL1 supplied with a voltage of a first driving power source VDD (or first power source) and a second power line PL2 supplied with a voltage of a second driving power source (or second power source). According to some embodiments, the light emitting unit EMU may include the light emitting element LD including a first electrode AE connected to the first driving power source VDD via the pixel circuit PXC and the first power line PL1 and a second electrode CE connected to the second driving power source VSS via the second power line PL2. The first electrode AE may be an anode, and the second electrode CE may be a cathode. The first driving power source VDD and the second driving power source VSS may have different potentials. A potential difference of the first and second driving power sources VDD and VSS may be set to a threshold voltage or higher of the light emitting element LD during an emission period.

When a sub-pixel SPX is located on an ith pixel row and a jth pixel column in the display area DA, a pixel circuit PXC of the sub-pixel SPX (or the sub-pixel) may be electrically connected to an ith scan line Si and a jth data line Dj. Also, the pixel circuit PXC may be electrically connected to an ith control line CLi and a jth sensing line SENj.

The above-described pixel circuit PXC may include first to third transistors T1, T2, and T3 and a storage capacitor Cst.

The first transistor T1 may be a driving transistor for controlling a driving current applied to the light emitting element LD, and be electrically connected between the first driving power source VDD and the light emitting element LD. Specifically, a first terminal of the first transistor T1 may be electrically connected to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of driving current applied from the first driving power source VDD to the light emitting element LD through the second node N2 according to a voltage applied to the first node N1. According to some embodiments, the first terminal of the first transistor T1 may be a drain electrode, and the second terminal of the first transistor T1 may be a source electrode. However, embodiments according to the present disclosure are not limited thereto. According to some embodiments, the first terminal may be the source electrode, and the second terminal may be the drain electrode.

The second transistor T2 may be a switching transistor for selecting the sub-pixel SPX in response to a scan signal and activating the sub-pixel SPX, and be electrically connected between the data line Dj (e.g., the jth data line) and the first node N1. A first terminal of the second transistor T2 may be electrically connected to the data line Dj, a second terminal of the second transistor T2 may be electrically connected to the first node N1 (or the gate electrode of the first transistor T1), and a gate electrode of the second transistor T2 may be electrically connected to the scan line Si (e.g., the ith scan line). The first terminal and the second terminal of the second transistor T2 are different terminals. For example, when the first terminal is a drain electrode, the second terminal may be a source electrode.

The second transistor T2 may be turned on when a scan signal having a gate-on voltage (e.g., a high level voltage) is supplied from the scan line Si, to electrically connect the data line Dj and the first node N1 to each other. The first node N1 may be a point at which the second terminal of the second transistor T2 and the gate electrode of the first transistor T1 are connected to each other, and the second transistor T2 may transfer a data signal to the gate electrode of the first transistor T1.

The third transistor T3 may electrically connect the first transistor T1 to the sensing line SENj (e.g., the jth sensing line), thereby acquiring a sensing signal through the sensing line SENj and detecting a characteristic of the sub-pixel SPX, including the threshold voltage of the first transistor T1, and the like. Information on the characteristic of the sub-pixel SPX may be used to convert image data such that a characteristic deviation between sub-pixels SPX can be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi (e.g., the ith control line). The first terminal may be a drain electrode, and the second terminal may be a source electrode.

The third transistor T3 may be an initialization transistor for initializing the second node N2, and be turned on when a sensing control signal is supplied from the control line CLi, to transfer a voltage of an initialization power source to the second node N2. Accordingly, the storage capacitor Cst electrically connected to the second node N2 may be initialized.

The storage capacitor Cst may include a lower electrode LE (or first storage electrode) and an upper electrode UE (or second storage electrode). The lower electrode LE may be electrically connected to the first node N1, and the upper electrode UE may be electrically connected to the second node N2. The storage capacitor Cst may charge a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

Although embodiments in which the first to third transistors T1, T2, and T3 are all N-type transistors are illustrated in FIG. 6, embodiments according to the present disclosure are not limited thereto. For example, at least one of the above-described first to third transistors T1, T2, and T3 may be changed to a P-type transistor. The structure of the pixel circuit PXC may be variously modified and embodied.

FIG. 7 is a schematic sectional view illustrating aspects of the light emitting element shown in FIG. 6 according to some embodiments. FIG. 8 is a schematic sectional view illustrating further details of the light emitting element shown in FIG. 6 according to some embodiments.

Referring to FIG. 7, the light emitting element LD may include a first electrode AE, an organic light emitting portion EL, and a second electrode CE. According to some embodiments, the first electrode AE, the organic light emitting portion EL, and the second electrode CE may be sequentially stacked.

According to some embodiments, the first electrode AE may be patterned to correspond to first to third sub-pixels SPX1, SPX2, and SPX3.

According to some embodiments, the organic light emitting portion EL may be provided on the first electrode AE. The organic light emitting portion EL may be in contact with the first electrode AE. The organic light emitting portion EL may have a multi-layer thin film structure including a plurality of light generation layers. The organic light emitting portion EL may include a hole injection layer HIL, a hole transport layer HTL, a light emitting layer EML, an electron transport layer ETL, and an electron injection layer EIL, which are sequentially stacked.

The hole injection layer HIL may be an organic layer located between the first electrode AE and the hole transport layer HTL to allow holes to be smoothly injected from the first electrode AE to the light emitting layer EML. The hole transport layer HTL may be located between the hole injection layer HIL and the light emitting layer EML to receive holes provided from the first electrode AE and transport the holes to the light emitting layer EML.

The electron injection layer EIL may be located between the electron transport layer ETL and the second electrode CE. The electron transport layer ETL may be located on the light emitting layer EML to receive electrons provided from the second electrode CE and transport the electrons to the light emitting layer EML.

The light emitting layer EML may be an area in which light is generated by recombination of electrons and holes, which are supplied from the first electrode AE and the second electrode CE. The light emitting layer EML may include an organic light emitting material such as a high molecular organic material or a low molecular organic material, which emits light of a color (e.g., a set or predetermined color). For example, the light emitting layer EML may be made of an organic material emitting blue light. However, embodiments according to the present disclosure are not limited thereto. According to some embodiments, the light emitting layer EML may be made of an organic material emitting red or green light or be made of an inorganic material or a quantum dot.

According to some embodiments, the second electrode CE may be integrally provided. The second electrode CE may be located on the organic light emitting portion EL. The second electrode CE may be integrally formed in light emitting elements LD.

Referring to FIG. 8, according to some embodiments, an organic light emitting portion EL may include a plurality of light generation layers. According to some embodiments, the organic light emitting portion EL may include a first organic light emitting portion ELa, a charge generation layer CGL, and a second organic light emitting portion ELb. According to some embodiments, a first electrode AE, the first organic light emitting portion ELa, the charge generation layer CGL, the second organic light emitting portion ELb, and a second electrode CE may be sequentially stacked.

The first organic light emitting portion ELa may be provided in a structure in which a hole injection layer HIL, a first hole transport layer HTLa, a first organic light emitting layer EMLa, and a first electron transport layer ETLa are sequentially stacked. The second organic light emitting portion ELb may be provided in a structure in which a second hole transport layer HTLb, a second organic light emitting layer EMLb, a second electron transport layer ETLb, and an electron injection layer EIL are sequentially stacked.

According to some embodiments, a buffer layer may be located on the first organic light emitting layer EMLa and the second organic light emitting layer EMLb. The buffer layer may include an electron transporting compound.

The charge generation layer CGL may function to supply charges to the first organic light emitting portion ELa and the second organic light emitting portion ELb. The charge generation layer CGL may include an n-type charge generation layer n-CGL for supplying electrons to the first organic light emitting portion ELa and a p-type charge generation layer p-CGL for supplying holes to the second organic light emitting portion ELb. The n-type charge generation layer n-CGL may include a metal material as a dopant.

In FIG. 8, it is illustrated that two organic light emitting portions ELa and ELb of a light emitting element LD are stacked. However, embodiments according to the present disclosure are not limited thereto. For example, three or four or more organic light emitting portions may be stacked in the light emitting element LD.

FIG. 9 is a schematic sectional view illustrating aspects of a pixel including the light emitting element shown in FIG. 7 or 8 according to some embodiments.

Referring to FIGS. 1 and 9, the display device DD may include a display area DA, and the display area DA may include first to third sub-pixel areas SPA1, SPA2, and SPA3, and a non-emission area NEA. According to some embodiments, the first sub-pixel area SPA1 may be an area in which light of a first color of a first sub-pixel SPX1 is emitted. The second sub-pixel area SPA2 may be an area in which light of a second color of a second sub-pixel SPX2 is emitted. The third sub-pixel area SPA3 may be an area in which light of a third color of a third sub-pixel SPX3 is emitted. For example, the first sub-pixel area SPA1 may emit light in a red wavelength band, the second sub-pixel area SPA2 may emit light in a green wavelength band, and the third sub-pixel area SPA3 may emit light in a blue wavelength band.

According to some embodiments, emission areas of the display area DA may correspond to the first to third sub-pixel areas SPA1, SPA2, and SPA3. The first to third sub-pixel areas SPA1, SPA2, and SPA3 and the non-emission area NEA may be defined by a bank BNK of a light control layer LCL.

Referring to FIG. 9, although embodiments in which the first to third sub-pixel areas SPA1, SPA2, and SPA3 are adjacent to each other in a direction intersecting the third direction DR3 is illustrated, embodiments according to the present disclosure are not necessarily limited thereto.

According to some embodiments, a pixel PXL may include a pixel circuit layer PCL, a display element layer DPL, an encapsulation layer TFE, the light control layer LCL, and a color filter layer CFL, which are sequentially located in the third direction DR3 on a substrate SUB.

Circuit elements (e.g., the first to third transistors T1, T2, and T3 shown in FIG. 6) and signal lines electrically connected to the circuit elements may be located in the pixel circuit layer PCL. The pixel circuit layer PCL may be located on the substrate SUB. The pixel circuit layer PCL may include a first transistor T1, a buffer layer BFL, a gate insulating layer GI, an interlayer insulating layer ILD, a passivation layer PVX, and a via layer VIA. Although one first transistor T1 is illustrated as an example, a sub-pixel SPX may include a plurality of transistors for driving a light emitting element LD and at least one capacitor.

The buffer layer BFL may be located on the substrate SUB. The buffer layer BFL may prevent or reduce instances of contaminants or impurities being diffused from an outside. The buffer layer BFL may prevent or reduce instances of contaminants or impurities being diffused into the first transistor T1 provided on the substrate SUB, thereby relatively improving the flatness of the substrate SUB. The buffer layer BFL may be provided as a single layer, but be provided as a multi-layer. The buffer layer BFL may be an inorganic insulating layer including an inorganic material. The inorganic insulating layer may include, for example, at least one of silicon nitride (SiNₓ), silicon oxide (SiOₓ), silicon oxynitride (SiOₓN_{y}), or a metal oxide such as aluminum oxide (AlOₓ). When the buffer layer BFL is provided as the multi-layer, layers constituting the multi-layer may be formed of the same material or be formed of different materials. The buffer layer BFL may be omitted in some cases.

The first transistor T1 may include a semiconductor pattern SCP, a gate electrode GE, a first terminal TE, and a second terminal TE2. The first terminal TE1 may be any one of a source electrode and a drain electrode, and the second terminal TE2 may be the other of the source electrode and the drain electrode. According to some embodiments, when the first terminal TE1 is the drain electrode, the second electrode TE2 may be a source electrode.

The semiconductor pattern SCP may be provided and/or formed on the buffer layer BFL. The semiconductor pattern SCP may include a first region in contact with the first terminal TE1, a second region in contact with the second terminal TE2, and a channel region between the first region and the second region. The channel region may overlap the gate electrode GE of the first transistor T1. The semiconductor pattern SCP may be a semiconductor pattern made of amorphous silicon, poly-silicon, low temperature poly-silicon, an oxide semiconductor, an organic semiconductor, or the like. The channel region is, for example, a semiconductor pattern undoped with an impurity, and may be an intrinsic semiconductor. The first region and the second region may correspond to a semiconductor pattern doped with the impurity. According to some embodiments, the first terminal TE1 may be electrically connected to the light emitting element LD through connection electrodes CNE1 and CNE2.

The gate insulating layer GI may be provided (or formed) over the semiconductor pattern SCP. The gate insulating layer GI may be an inorganic insulating layer including an inorganic material. The gate insulating layer GI may include the same material as the buffer layer BFL or include at least one material selected from the materials illustrated as the material constituting the buffer layer BFL. According to some embodiments, the gate insulating layer GI may be provided as an organic insulating layer including an organic material. The gate insulating layer GI may be provided as a single layer, but be provided as a multi-layer including at least two layers.

The gate electrode GE may be provided (or formed) on the gate insulating layer GI to correspond to the channel region of the semiconductor pattern SCP. The gate electrode GE may be provided on the gate insulating layer GI to overlap the channel region of the semiconductor pattern SCP. The gate electrode GE may form a single layer, using one selected from the group consisting of copper (Cu), molybdenum (Mo), tungsten (W), aluminum neodymium (AlNd), titanium (Ti), aluminum (Al), and silver (Ag), or a mixture thereof, or be formed in a double-layer or multi-layer structure including molybdenum (Mo), titanium (Ti), copper (Cu), aluminum (Al), and silver (Ag), which are low resistance materials, to reduce wiring resistance.

The interlayer insulating layer ILD may be provided (or formed) over the gate electrode GE. A first connection electrode CNE1 may be located on the interlayer insulating layer ILD. The first connection electrode CNE1 may be electrically connected to the first terminal TE1 through a contact hole penetrating the gate insulating layer GI and the interlayer insulating layer ILD.

The passivation layer PVX may be provided (or formed) over the first connection electrode CNE1. A second connection electrode CNE2 may be located on the passivation layer PVX. The second connection electrode CNE may be electrically connected to the first connection electrode CNE1 through a contact hole penetrating the passivation layer PVX.

The passivation layer PVX may be provided in a form including an inorganic insulating layer located on an organic insulating layer or the organic insulating layer located on the inorganic insulating layer. The inorganic insulating layer may include, for example, at least one of silicon oxide (SiOₓ), silicon nitride (SiNₓ), silicon oxynitride (SiOₓN_{y}), or a metal oxide such as aluminum oxide (AlOₓ). The organic insulating layer may include, for example, at least one of acryl resin, epoxy resin, phenol resin, polyamide resin, polyimide resin, unsaturated polyester resin, poly-phenylene ether resin, poly-phenylene sulfide resin, or benzocyclobutene resin.

The via layer VIA may be entirely provided (or formed) on the passivation layer PVX. The via layer VIA may be an inorganic insulating layer including an inorganic material or an organic insulating layer including an organic material.

The display element layer DPL may be located on the via layer VIA. The display element layer DPL may include the light emitting element LD and a pixel defining layer PDL. The light emitting element LD and the pixel defining layer PDL may be provided (or formed) on the via layer VIA. The light emitting element LD may include a first light emitting element LD1 located in the first sub-pixel area SPA1, a second light emitting element LD2 located in the second sub-pixel area SPA2, and a third light emitting element LD3 located in the third sub-pixel area SPA3.

Each of the light emitting elements LD may include a first electrode AE, an organic light emitting portion EL, and a second electrode CE. The light emitting element LD may be electrically connected to a pixel circuit (e.g., the pixel circuit PXC shown in FIG. 6) of a corresponding pixel.

The first electrode AE may be provided (or formed) on the via layer VIA of a corresponding pixel. The first electrode AE may be an anode electrode of the light emitting element LD. The first electrode AE may be electrically connected to the first terminal TE1 through a contact portion corresponding to the first electrode AE. According to some embodiments, the first electrode AE may include anode electrodes corresponding to the first to third sub-pixel areas SPA1, SPA2, and SPA3. The first electrode AE may be patterned to correspond to the first to third sub-pixel areas SPA1, SPA2, and SPA3.

The first electrode AE may be made of a conductive material (or substance). The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the first electrode AE may include a transparent conductive material (or substance). The transparent conductive material (or substance) may include a conductive oxide such as indium tin oxide (ITO), indium zinc oxide (IZO), zinc oxide (ZnOₓ), indium gallium zinc oxide (IGZO), or indium tin zinc oxide (ITZO), a conductive polymer such as poly (3,4-ethylenedioxythiophene (PEDOT), and the like. When the first electrode AE includes a transparent conductive material (or substance), a separate conductive layer made of an opaque metal for reflecting light emitted from the light emitting layer EML in an image display direction (or the encapsulation layer TFE) of a display device (e.g., the display device DD shown in FIG. 1) may be added.

The pixel defining layer PDL may define (or partition) an area in which the organic light emitting portion EL is located. The pixel defining layer PDL may expose at least one area of the first electrode AE. The pixel defining layer PDL may be an organic insulating layer made of an organic material. According to some embodiments, the pixel defining layer PDL may include a light absorption material or have a light absorber coated thereon, to absorb light introduced from the outside. For example, the pixel defining layer PDL may include a carbon-based black pigment. However, embodiments according to the present disclosure are not limited thereto. According to some embodiments, the pixel defining layer PDL may be an inorganic insulating layer made of an inorganic material.

The pixel defining layer PDL may be partially opened to include an opening exposing one area of the first electrode AE, and protrude in the third direction DR3 along circumferences of the emission areas from the via layer VIA. The pixel defining layer PDL may be located on the via layer VIA to define an area in which the organic light emitting portion EL is accommodated while being located on the first electrode AE. The organic light emitting portion EL may be located on the first electrode AE exposed by the opening of the pixel defining layer PDL.

The organic light emitting portion EL may have a multi-layer thin film structure including a light generation layer which generates light. The organic light emitting portion EL may emit one light among light of red, light of green, and light of blue, but embodiments according to the present disclosure are not limited thereto. For example, the organic light emitting portion EL may include a white light emitting layer emitting light of white. The design inside the organic light emitting portion EL may vary according to a color of light to be implemented.

The second electrode CE may be located on the organic light emitting portion EL and the pixel defining layer PDL. The second electrode CE may be provided in a plate shape throughout the entire display area DA. The second electrode CE may be located at an outermost portion (or uppermost portion) of the light emitting element LD.

The second electrode CE may be a thin film metal layer having a thickness to a degree to which light emitted from the organic light emitting portion EL can be transmitted therethrough. The second electrode CE may be formed of a metal material to have a relatively thin thickness or be formed of a transparent conductive material. The second electrode CE may include at least one of various transparent conductive materials including indium tin oxide, indium zinc oxide, indium tin zinc oxide, aluminum zinc oxide, gallium zinc oxide, zinc tin oxide, or gallium tin oxide, and be implemented transparent or translucent (or substantially transparent or translucent) to satisfy a transmittance value or threshold (e.g., a set or predetermined transmittance value or threshold). Accordingly, light emitted from the organic light emitting portion EL located on the bottom of the second electrode CE may be emitted in an upper direction of the encapsulation layer TFE while passing through the second electrode CE.

The encapsulation layer TFE may be entirely provided (or formed) over the second electrode CE. The encapsulation layer TFE may be in contact with the second electrode CE. In FIG. 6, embodiments in which the encapsulation layer TFE is formed as a single layer over the second electrode CE is illustrated. However, embodiments according to the present disclosure are not limited thereto.

According to some embodiments, the encapsulation layer TFE may be formed as one layer. The encapsulation layer TFE may have an encapsulation layer thickness TFE_T.

The encapsulation layer TFE in accordance with the present disclosure may be deposited using Plasma-Enhanced Atomic Layer Deposition (PEALD) or Atomic Layer Deposition (ALD). The encapsulation layer TFE may have a thickness of 2000 nm or less (or according to some embodiments, a thickness of 1000 nm or less.

According to some embodiments, the encapsulation layer thickness TFE_T may be 10 nm to 2000 nm. According to some embodiments, the encapsulation layer thickness TFE_T may be 10 nm to 1000 nm. According to some embodiments, the encapsulation layer thickness TFE_T may be 100 nm to 2000 nm. According to some embodiments, the encapsulation layer thickness TFE_T may be 100 nm to 1000 nm. According to some embodiments, the encapsulation layer thickness TFE_T may be 150 nm to 1000 nm. When the encapsulation layer thickness TFE_T is greater than 2000 nm, there may exist a risk that the light output efficiency of the display device DD will be reduced. When the encapsulation layer thickness TFE_T is smaller than 10 nm, the light emitting element LD may not be appropriately encapsulated. According to some embodiments, when the encapsulation layer thickness TFE_T is 1000 nm or less, the light output efficiency of the display device DD may increase by 10% to 15%, as compared with a display device in which the encapsulation layer thickness TFE_T is greater than 1000 nm.

The encapsulation layer thickness TFE_T may be an average thickness from a bottom surface to a top surface of the encapsulation layer TFE. The bottom surface of the encapsulation layer TFE may be a surface in contact with the display element layer DPL, and the top surface of the encapsulation layer TFE may be a surface in contact with the light control layer LCL.

The encapsulation layer TFE may be an inorganic layer including an inorganic material. The encapsulation layer TFE may protect the sub-pixel SPX from a foreign matter such as a dust particle. The encapsulation layer TFE may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The light control layer LCL may be located on the encapsulation layer TFE. According to some embodiments, a bottom surface of the light control layer LCL may be in contact with the top surface of the encapsulation layer TFE. The light control layer LCL may include the bank BNK, a first capping layer CAP1, a light control pattern layer CCL, and a low refractive layer LRL.

The bank BNK may be located on the encapsulation layer TFE. The bank BNK may be located between the first to third sub-pixel areas SPA1, SPA2, and SPA3 (or the first to third sub-pixels SPX1, SPX2, and SPX3 shown in FIG. 1) or in boundaries between the first to third sub-pixel areas SPA1, SPA2, and SPA3, and include openings respectively overlapping with the first to third sub-pixel areas SPA1, SPA2, and SPA3. For example, a desired kind and a desired amount of light control pattern layer CCL may be supplied to a space partitioned by the opening formed by the bank BNK.

The bank BNK may define the first to third sub-pixel areas SPA1, SPA2, and SPA3 and the non-emission area NEA. The first to third sub-pixel areas SPA1, SPA2, and SPA3 may be areas corresponding to the openings of the bank BNK, and the non-emission area NEA may be an area corresponding to the bank BNK. For example, the first to third sub-pixel areas SPA1, SPA2, and SPA3 may be areas overlapping with the openings of the bank BNK when viewed on a plane, and the non-emission area NEA may be an area overlapping with the bank BNK when viewed on a plane. When viewed on a plane, the bank BNK may surround the first to third sub-pixel areas SPA1, SPA2, and SPA3.

The bank BNK may include an organic material such as acryl resin, epoxy resin, phenol resin, polyamide resin, polyimide resin, polyester resin, poly-phenylene sulfide resin, or benzocyclobutene (BCB). However, the present disclosure is not necessarily limited thereto, and the bank BNK may include various kinds of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The bank BNK may include at least one light blocking and reflective material. Accordingly, light leakage between adjacent sub-pixels can be prevented or reduced. For example, the bank BNK may include a black pigment, but the present disclosure is not necessarily limited thereto.

The light control pattern layer CCL may be accommodated in the openings of the bank BNK, and be located in areas overlapping with the first to third sub-pixel areas SPA1, SPA2, and SPA3. The light control pattern layer CCL may include a first wavelength conversion layer CCL1, a second wavelength conversion layer CCL2, and a light transmission layer TL, which respectively correspond to the first to third sub-pixel areas SPA1, SPA2, and SPA3. The first wavelength conversion layer CCL1 may be located in the first sub-pixel area SPA1, the second wavelength conversion layer CCL2 may be located in the second sub-pixel area SPA2, and the light transmission layer TL may be located in the third sub-pixel area SPA3. The first wavelength conversion layer CCL1, the second wavelength conversion layer CCL2, and the light transmission layer TL may be in contact with the top surface of the encapsulation layer TFE.

According to some embodiments, the first to third sub-pixel areas SPA1, SPA2, and SPA3 may include the first to third light emitting elements LD1, LD2, LD3 emitting light of the same color. For example, the first to third light emitting elements LD1, LD2, LD3 may emit light of a third color (or blue). The first wavelength conversion layer CCL1, the second wavelength conversion layer CCL2, and the light transmission layer TL, which include color conversion particles, are respectively located on the first to third sub-pixel areas SPA1, SPA2, SPA3, so that a full-color image can be located.

The first wavelength conversion layer CCL1 and the second wavelength conversion layer CCL2 may include color conversion particles QD (or wavelength conversion particles). According to some embodiments, the first wavelength conversion layer CCL1 and the second wavelength conversion layer CCL2 may include the color conversion particles QD for converting light of the third color (or in a third wavelength band), which is incident from the light emitting element LD, into light of a first color (or specific color) (or in a first wavelength band) or a second color (or specific color) (or in a second wavelength band) and emitting the converted light.

The first wavelength conversion layer CCL1 may include first color conversion particles for converting light of the third color, which is emitted from the first light emitting element LD1, into light of the first color (or light of red). For example, the first wavelength conversion layer CCL1 may include a plurality of quantum dot particles QD dispersed in a matrix material (e.g., a predetermined matrix material) such as base resin. The first quantum dot particles QD of the first wavelength conversion layer CCL1 may absorb blue light and emit red light by shifting a wavelength of the blue light according to energy transition.

The second wavelength conversion layer CCL2 may include second color conversion particles for converting light of the third color, which is emitted from the second light emitting element LD2, into light of the second color (or light of green). For example, the second wavelength conversion layer CCL2 may include a plurality of quantum dot particles QD dispersed in a matrix material (e.g., a set or predetermined matrix material) such as base resin. The second quantum dot particles QD of the second wavelength conversion layer CCL2 may absorb blue light and emit green light by shifting a wavelength of the blue light according to energy transition.

The light transmission layer TL may be provided to efficiently use light of the third color (or blue), which is emitted from the third light emitting element LD3. According to some embodiments, when the third light emitting element LD3 is a blue light emitting element emitting light of blue and the third sub-pixel area SPA3 is a blue sub-pixel area, the light transmission layer TL may include at least one kind of scatterer SCT to efficiently use light emitted from the third light emitting element LD3.

In the present disclosure, a distance between the second electrode CE and the light control pattern layer CCL may be 10 nm to 2000 nm. According to some embodiments, the distance between the second electrode CE and the light control pattern layer CCL may be 10 nm to 1000 nm. According to some embodiments, the distance between the second electrode CE and the light control pattern layer CCL may be 100 nm to 2000 nm. According to some embodiments, the distance between the second electrode CE and the light control pattern layer CCL may be 100 nm to 1000 nm. According to some embodiments, the distance between the second electrode CE and the light control pattern layer CCL may be 150 nm to 1000 nm. The distance between the second electrode CE and the light control pattern layer CCL may be defined as an average distance between a top surface of the second electrode CE and a bottom surface of the light control pattern layer CCL. The distance between the second electrode CE and the light control pattern layer CCL may correspond to a distance between the top surface of the second electrode CE and at least one of the first wavelength conversion layer CCL1, the second wavelength conversion layer CCL2, or the light transmission layer TL in the third direction DR3.

The first capping layer CAP1 may be entirely arranged over the bank BNK and the light control pattern layer CCL. The first capping layer CAP1 may be in contact with the bank BNK and the light control pattern layer CCL. The first capping layer CAP1 may prevent or reduce instances of contaminants such as moisture or foreign matter infiltrating into the light control pattern layer CCL. The first capping layer CAP1 may include an inorganic material. For example, the first capping layer CAP1 may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first capping layer CAP1 may have a thickness of 100 nm to 1000 nm. When the thickness of the first capping layer CAP1 is smaller than 100 nm, a risk that moisture or a foreign matter will infiltrate into the bank BNK and the light control pattern layer CCL may be increased. When the thickness of the first capping layer CAP1 is greater than 1000 nm, the thickness of the display device DD is excessively increased, and therefore, the light output efficiency of the display device may be reduced.

According to some embodiments, the display device DD may further include a protective layer for protecting the bottom of the light control pattern layer CCL, separately from the encapsulation layer TFE. The protective layer for protecting the bottom of the light control pattern layer CCL may have the same thickness range as the first capping layer CAP1. For example, the protective layer for protecting the bottom of the light control pattern layer CCL may have a thickness of 100 nm to 1000 nm. The protective layer for protecting the bottom of the light control pattern layer CCL may include an inorganic material.

According to some embodiments, the low refractive layer LRL may be located on the first capping layer CAP1. According to some embodiments, the low refractive layer LRL may have a refractive index of 1.1 to 1.4. According to some embodiments, the low refractive layer LRL may have a refractive index difference of 0.5 or more from a layer located under the low refractive layer LRL. The low refractive layer LRL may have a refractive index lower than a refractive index of the light control pattern layer CCL located under the low refractive layer LRL. The low refractive layer LRL may have a refractive index higher than a refractive index of a color filter CF located above the low refractive layer LRL. The low refractive layer LRL may adjust a path of light emitted from the light control pattern layer CCL (or the display element layer DPL). For example, the low refractive layer LRL may change a path of obliquely incident light to a direction perpendicular to a planarization layer OC. The low refractive layer LRL may include a polymer material and a silica-based material.

According to some embodiments, a second capping layer CAP2 may be located on the low refractive layer LRL. The second capping layer CAP2 may prevent or reduce instances of contaminants such as moisture or foreign matter infiltrating into the low refractive layer LRL. The second capping layer CAP2 may include an inorganic material.

In accordance with the present disclosure, a distance between the display element layer DPL and the light control layer LCL may be 10 nm to 2000 nm. The distance between the display element layer DPL and the light control layer LCL may be defined as a distance from the top surface of the second electrode CE to the bottom surface of the light control pattern layer CCL. For example, the distance between the display element layer DPL and the light control layer LCL may be the distance (e.g., an average distance) between the second electrode CE and the light control pattern layer CCL. According to some embodiments, the distance between the display element layer DPL and the light control layer LCL may be 10 nm to 1000 nm. According to some embodiments, the distance between the display element layer DPL and the light control layer LCL may be 100 nm to 2000 nm. According to some embodiments, the distance between the display element layer DPL and the light control layer LCL may be 100 nm to 1000 nm. According to some embodiments, the distance between the display element layer DPL and the light control layer LCL may be 150 nm to 1000 nm. According to some embodiments, when the distance between the display element layer DPL and the light control layer LCL is 1000 nm, the light output efficiency of the display device DD may increase by 10% to 15%, as compared with a display device in which the distance between the display element layer DPL and the light control layer LCL is greater than 1000 nm.

According to some embodiments, the color filter layer CFL may be located on the light control layer LCL. According to some embodiments, the color filter layer CFL may be located on the second capping layer CAP2. The color filter layer CFL may include color filters CF and the planarization layer OC. The color filters CF may include first to third color filters CF1, CF2, and CF3 corresponding to each of the first to third sub-pixel areas SPA1, SPA2, and SPA3.

According to some embodiments, the first color filter CF1, the second color filter CF2, and the third color filter CF3 may be a red color filter, a green color filter, and a blue color filter, respectively, but the present disclosure is not necessarily limited thereto.

According to some embodiments, the first color filter CF1 may be located on the second capping layer CAP2, corresponding to the first sub-pixel area SPA1, and allow light emitted from the first light emitting element LD1 and the first wavelength conversion layer CCL1 to be selectively transmitted therethrough. For example, the first color filter CF1 may overlap the first sub-pixel area SPA1 when viewed on a plane. According to some embodiments, the first color filter CF1 may overlap the first wavelength conversion layer CCL1 in the third direction DR3. The first color filter CF1 may include a color material for allowing light of the first color (or red) to be selectively transmitted therethrough. For example, when the first sub-pixel area SPA1 is a red sub-pixel area, the first color filter CF1 may include a red color filter material.

According to some embodiments, the second color filter CF2 may be located on the second capping layer CAP2, corresponding to the second sub-pixel area SPA2, and allow light emitted from the second light emitting element LD2 and the second wavelength conversion layer CCL2 to be selectively transmitted therethrough. For example, the second color filter CF2 may overlap the second sub-pixel area SPA2 when viewed on a plane. According to some embodiments, the second color filter CF2 may overlap the second wavelength conversion layer CCL2 in the third direction DR3. The second color filter CF2 may include a color material for allowing light of the second color (or green) to be selectively transmitted therethrough. For example, when the second sub-pixel area SPA2 is a green sub-pixel area, the second color filter CF2 may include a green color filter material.

According to some embodiments, the third color filter CF3 may be located on the second capping layer CAP2, corresponding to the third sub-pixel area SPA3, and allow light emitted from the third light emitting element LD3 and the light transmission layer TL to be selectively transmitted therethrough. For example, the third color filter CF3 may overlap the third sub-pixel area SPA3 when viewed on a plane. According to some embodiments, the third color filter CF3 may overlap the light transmission layer TL in the third direction DR3. The third color filter CF3 may include a color material for allowing light of the third color (or blue) to be selectively transmitted therethrough. For example, when the third sub-pixel area SPA3 is a blue sub-pixel area, the third color filter CF2 may include a blue color filter material.

According to some embodiments, the second color filter CF2, the first color filter CF1, and the third color filter CF3 may be sequentially stacked in the third direction DR3. For example, the first color filter CF1 may be arranged to cover the second color filter CF2 in the non-emission area NEA after the second color filter CF2 is located. In addition, after the first color filter CF1 is arranged or formed, the third color filter CF3 may be arranged or formed.

According to some embodiments, the planarization layer OC may be arranged over the first to third color filters CF1, CF2, and CF3. The planarization layer OC may cover the first to third color filters CF1, CF2, and CF3. The planarization layer OC is not particularly limited as long as it includes a material having excellent planarization characteristics and excellent light transmittance. The planarization layer OC may include an organic material or an inorganic material. According to some embodiments, when the planarization layer OC includes an organic material, the planarization layer OC may include at least one of acryl resin, epoxy resin, phenol resin, polyamide resin, polyimide resin, unsaturated polyester resin, poly-phenylene ether resin, poly-phenylene sulfide resin, or benzocyclobutene resin.

According to some embodiments, the planarization layer OC may have a thickness of 1000 nm to 10000 nm. According to some embodiments, the planarization layer OC may have a thickness of 1500 nm to 10000 nm. When the planarization layer OC has a thickness smaller than 1000 nm, planarization characteristics may be relatively decreased. When the planarization layer OC has a thickness greater than 10000 nm, the thickness of the display device DD may be excessively increased, and the light output efficiency of the display device DD can be relatively reduced.

According to some embodiments, the display device DD may further include an anti-reflection (AR) film located on the planarization layer OC. The AR film may be located at an outermost portion of the display device DD. According to some embodiments, the display device DD may further include a stack structure for reducing external light reflection of the display device DD at an outermost portion of the display device DD.

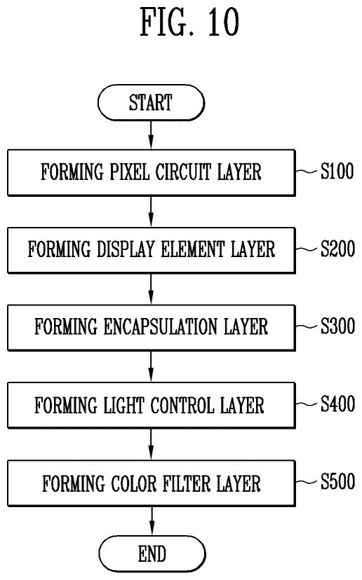

Hereinafter, a method of manufacturing the display device DD will be described in more detail with reference to FIG. 10. Some descriptions of portions overlapping with those described above may be omitted. FIG. 10 is a flowchart illustrating aspects of a method of manufacturing the display device according to some embodiments of the present disclosure. Although FIG. 10 illustrates various operations in a method of manufacturing a display device, embodiments according to the present disclosure are not limited thereto, and according to some embodiments, the method of manufacturing the display device may include additional operations or fewer operations, or the order of operations may vary, unless otherwise stated or implied, without departing from the spirit and scope of embodiments according to the present disclosure.

Referring to FIG. 10, the method of manufacturing the display device DD may include operation S100 of forming a pixel circuit layer, operation S200 of forming a display element layer, operation S300 of forming an encapsulation layer, operation S400 of forming a light control layer, and operation S500 of forming a color filter layer.

In the operation S100 of forming the pixel circuit layer, a pixel circuit layer including a pixel circuit for driving light emitting elements LD may be formed (e.g., patterned) on a substrate SUB. The pixel circuit layer PCL may be formed (e.g., patterned) to include conductive layers and insulating layers located between the conductive layers.

According to some embodiments, components located on the substrate SUB may be formed (e.g., patterned) through an ordinary patterning process (e.g., a photolithography process or the like) using a mask.

The operation S200 of forming the display element layer may include an operation of forming a pixel defining layer PDL and the light emitting elements LD. An operation of forming each of the light emitting elements LD may include an operation of forming a first electrode AE, an organic light emitting portion EL, and a second electrode CE.

The first electrode AE may be formed (e.g., patterned) on the pixel circuit layer PCL. According to some embodiments, the first electrode AE may be deposited on the pixel circuit layer PCL, to be etched such that at least a portion of the pixel circuit layer PCL is exposed.

In the present disclosure, as long as separate description of a deposition process used to form (e.g., pattern) a component of the display device DD is not made, at least one of a sputtering process a Chemical Vapor Deposition (CVD) process, or an Atomic Layer Deposition (ALD) process may be used as the process for depositing the component of the display device DD. In the present disclosure, as long as separate description of an etching process used to form (e.g., pattern) a component of the display device DD is not made, at least one of a wet etching process or a dry etching process may be used as the process for etching the component of the display device DD. However, embodiments according to the present disclosure are not limited to a specific example.

The pixel defining layer PDL may be formed on the pixel circuit layer PCL. The pixel defining layer PDL may be deposited on the pixel circuit layer PCL and the first electrode AE. The pixel defining layer PDL may be etched to expose at least a portion of the first electrode AE. The pixel defining layer PDL may be etched to overlap the other portion of the first electrode AE.

The organic light emitting portion EL may be formed on the first electrode AE. The organic light emitting portion EL may be formed to have a multi-layer thin film structure including a plurality of light generation layers.

The second electrode CE may be formed on the organic light emitting portion EL. The second electrode CE may be integrally formed on the organic light emitting portion EL. The second electrode CE may be integrally formed in the light emitting elements LD.

The operation S300 of forming the encapsulation layer may include an operation of forming an encapsulation layer TFE on the display element layer DPL. The encapsulation layer TFE may be formed on the second electrode CE.

The operation S300 of forming the encapsulation layer may include an operation of depositing the encapsulation layer TFE, using plasma-Enhanced Atomic Layer Deposition (PEALD) or Atomic Layer Deposition (ALD), and the encapsulation layer TFE may have a thickness of 2000 nm or less (or, according to some embodiments, a thickness of 1000 nm or less).

The operation S400 of forming the light control layer may include an operation of forming a light control layer LCL on the encapsulation layer TFE. The operation S400 of forming the light control layer may include an operation of forming a bank BNK, a first capping layer CAP1, a light control pattern layer CCL, a low refractive layer LRL, and a second capping layer CAP2.

The operation S500 of forming the color filter layer may include an operation of forming a color filter CF and a planarization layer OC on the light control layer LCL. In the operation S500 of forming the color filter layer, a color filter layer CFL may be formed on the second capping layer CAP2. The color filter CF may be formed on the second capping layer CAP2. The planarization layer OC may be formed over the color filter CF.

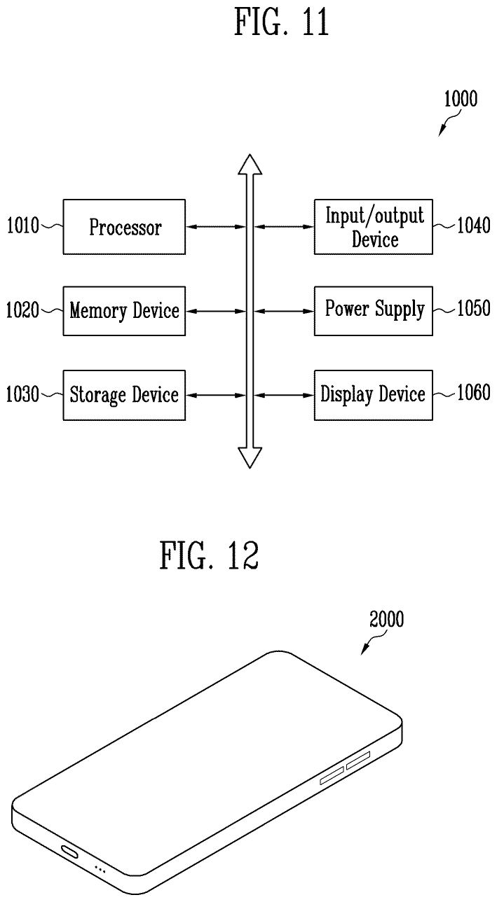

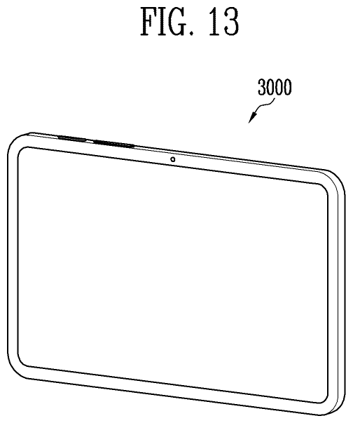

FIG. 11 is a schematic block diagram illustrating an electronic device 1000 including a display device in accordance with an embodiment. FIG. 12 is a schematic diagram illustrating an example where the electronic device 1000 of FIG. 11 is a smartphone. FIG. 13 is a schematic diagram illustrating an example where the electronic device 1000 of FIG. 11 is a tablet computer.

Referring to FIGS. 11 to 13, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 12, the electronic device 1000 may be a smartphone. In an embodiment, as illustrated in FIG. 13, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

According to some embodiments of the present disclosure, there can be provided a display device and a method of manufacturing a display device, in which the light output efficiency of the display device is relatively improved and the thickness of the display device is relatively decreased.

Aspects of some embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims, and their equivalents.

1 what is claimed is:

1. A display device comprising:
a display element layer including a light emitting element;
an encapsulation layer on the display element layer, the encapsulation layer being formed as a single layer; and
a light control layer overlapping with the encapsulation layer, the light control layer including a light control pattern layer including a first wavelength conversion layer, a second wavelength conversion layer, and a light transmission layer,
wherein the light emitting element includes a first electrode, an organic light emitting portion on the first electrode, and a second electrode on the organic light emitting portion, and
wherein a distance between a top surface of the second electrode and a bottom surface of the light control pattern layer is in a range of 10 nanometers (nm) to 2000 nm.

2. The display device of claim 1, wherein the encapsulation layer is deposited by using Plasma-Enhanced Atomic Layer Deposition (PEALD) or Atomic Layer Deposition (ALD).

3. The display device of claim 1, wherein the encapsulation layer has a thickness in a range of 10 nm to 1000 nm.

4. The display device of claim 1, wherein a bottom surface of the encapsulation layer is in contact with the second electrode, and
a top surface of the encapsulation layer is in contact with the first wavelength conversion layer, the second wavelength conversion layer, and the light transmission layer.

5. The display device of claim 1, wherein the encapsulation layer includes at least one of silicon oxide, silicon nitride, silicon oxynitride, aluminum nitride, aluminum oxide, zirconium oxide, hafnium oxide, or titanium oxide.

6. The display device of claim 1, further comprising a first capping layer on the light control pattern layer,
wherein the first capping layer includes an inorganic material, and has a thickness in a range of 100 nm to 1000 nm.

7. The display device of claim 6, further comprising a low refractive layer on the first capping layer,
wherein the low refractive layer has a refractive index in a range of 1.1 to 1.4 which is smaller than a refractive index of the light control pattern layer.

8. The display device of claim 1, further comprising a color filter layer on the light control layer,
wherein the color filter layer includes a first color filter, a second color filter, and a third color filter, and
wherein the first color filter allows light of red to be selectively transmitted therethrough,
the second color filter allows light of green to be selectively transmitted therethrough, and
the third color filter allows light of blue to be selectively transmitted therethrough.

9. The display device of claim 8, further comprising a planarization layer on the color filter layer,
wherein the planarization layer includes an organic material, and has a thickness in a range of 1000 nm to 10000 nm.

10. The display device of claim 1, further comprising:
a first sub-pixel area configured to emit light of a first color;
a second sub-pixel area configured to emit light of a second color;
a third sub-pixel area configured to emit light of a third color; and
a bank between the first to third sub-pixel areas,
wherein the first wavelength conversion layer is in the first sub-pixel area,
the second wavelength conversion layer is in the second sub-pixel area, and
the light transmission layer is in the third sub-pixel area.

11. The display device of claim 9, further comprising an anti-reflection film on the planarization layer.

12. A display device comprising:
a display area having pixels therein, the display area including a first sub-pixel area, a second sub-pixel area, and a third sub-pixel area;
a display element layer including a light emitting element forming the pixels;
an encapsulation layer on the display element layer; and
a light control layer overlapping with the display element layer,
wherein the light emitting element includes a first electrode, an organic light emitting portion on the first electrode, and a second electrode on the organic light emitting portion,
wherein the light control layer includes a light control pattern layer including a first wavelength conversion layer in the first sub-pixel area, a second wavelength conversion layer in the second sub-pixel area, and a light transmission layer in the third sub-pixel area, and
wherein a distance between a top surface of the second electrode and a bottom surface of the light control pattern layer is in a range of 10 nm to 1000 nm.

13. The display device of claim 12, wherein the encapsulation layer is formed as a single layer,
wherein a bottom surface of the encapsulation layer is in contact with the second electrode, and
a top surface of the encapsulation layer is in contact with the first wavelength conversion layer, the second wavelength conversion layer, and the light transmission layer, and
wherein the encapsulation layer includes an inorganic material.

14. The display device of claim 12, further comprising:
a first capping layer on the light control pattern layer; and
a low refractive layer on the first capping layer,
wherein the low refractive layer has a refractive index in a range of 1.1 to 1.4 which is lower than a refractive index of the light control pattern layer,
wherein the first capping layer is in contact with the light control pattern layer,
wherein the first capping layer includes an inorganic material, and has a thickness in a range of 100 nm to 1000 nm.

15. The display device of claim 12, further comprising:
a color filter layer on the light control layer; and
a planarization layer on the color filter layer,
wherein the color filter layer includes a first color filter, a second color filter, and a third color filter,
wherein the first color filter overlaps with the first sub-pixel area,
the second color filter overlaps with the second sub-pixel area, and
the third color filter overlaps with the third sub-pixel area, and
wherein the planarization layer includes an organic material, and has a thickness in a range of 1500 nm to 10000 nm.

16. The display device of claim 12, comprising a bank on the encapsulation layer,
wherein the bank includes an opening, and
wherein the opening overlaps with the first sub-pixel area, the second sub-pixel area, and the third sub-pixel area.

17. The display device of claim 16, wherein the first wavelength conversion layer and the second wavelength conversion layer include a quantum dot, and
wherein the light transmission layer includes a scatterer.

18. The display device of claim 15, further comprising an anti-reflection film on the planarization layer.

19. A method of manufacturing a display device, the method comprising:
forming a display element layer including a light emitting element;
forming an encapsulation layer on the display element layer; and
forming a light control layer overlapping the encapsulation layer,
wherein the light emitting element includes a first electrode, an organic light emitting portion on the first electrode, and a second electrode on the organic light emitting portion,
wherein the light control layer includes a light control pattern layer including a first wavelength conversion layer, a second wavelength conversion layer, and a light transmission layer,
wherein a distance between the second electrode and the light control pattern layer is in a range 10 nm to 2000 nm, and
wherein the forming of the encapsulation layer includes depositing the encapsulation layer, by using Plasma-Enhanced Atomic Layer Deposition (PEALD) or Atomic Layer Deposition (ALD).

20. The method of claim 19, wherein the encapsulation layer is formed as a single layer.

21. An electronic device, comprising:
a processor to provide input image data; and
a display device to display an image based on the input image data,
wherein the display device comprises: a display element layer including a light emitting element;
an encapsulation layer on the display element layer, the encapsulation layer being formed as a single layer; and
a light control layer overlapping with the encapsulation layer, the light control layer including a light control pattern layer including a first wavelength conversion layer, a second wavelength conversion layer, and a light transmission layer,
wherein the light emitting element includes a first electrode, an organic light emitting portion on the first electrode, and a second electrode on the organic light emitting portion, and
wherein a distance between a top surface of the second electrode and a bottom surface of the light control pattern layer is in a range of 10 nanometers (nm) to 2000 nm.
